(19) United States
(12) Patent Application Publication
(10) Pub. No.: US 2012/0156407 A1
(43) Pub. Date: Jun. 21, 2012

(54) HOUSING AND METHOD FOR MANUFACTURING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); HUA-YANG XU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/165,342

(22) Filed: Jun. 21, 2011

(30) Foreign Application Priority Data
Dec. 15, 2010 (CN) 201010589308.6

(51) Int. Cl. B32B 1/02; C23C 16/44

(52) U.S. Cl. 428/34.6; 428/34.1; 428/35.7; 427/255.7

(57) ABSTRACT

A housing includes a substrate; a color layer deposited on the substrate; and a pattern layer deposited on the color layer opposite to the substrate.

### BACKGROUND

1. Technical Field

The exemplary disclosure generally relates to housings and methods for manufacturing the housings.

2. Description of Related Art

Vacuum deposition is used to form a thin film or coating on the housings of portable electronic devices, to provide an attractive metallic appearance on the housing. To improve the appearance of the coating, the typical way is to use a laser-engraving machine to etch a pattern on the coating. However, using a laser-engraving machine to etch a pattern on the coating has a low efficiency rate and drives up the cost of manufacturing the housings.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary embodiment of a housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an embodiment of a housing with a substrate, a color layer, a pattern layer and a protection layer.

FIG. 2 illustrates a method for making the housing of FIG. 1, when a glue covers on the color layer.

FIG. 3 illustrates a method for making the housing of FIG. 1, when a pattern layer is deposited on the color layer.

FIG. 4 illustrates a method for making the housing of FIG. 1, when the glue is removed from the color layer.

### DETAILED DESCRIPTION

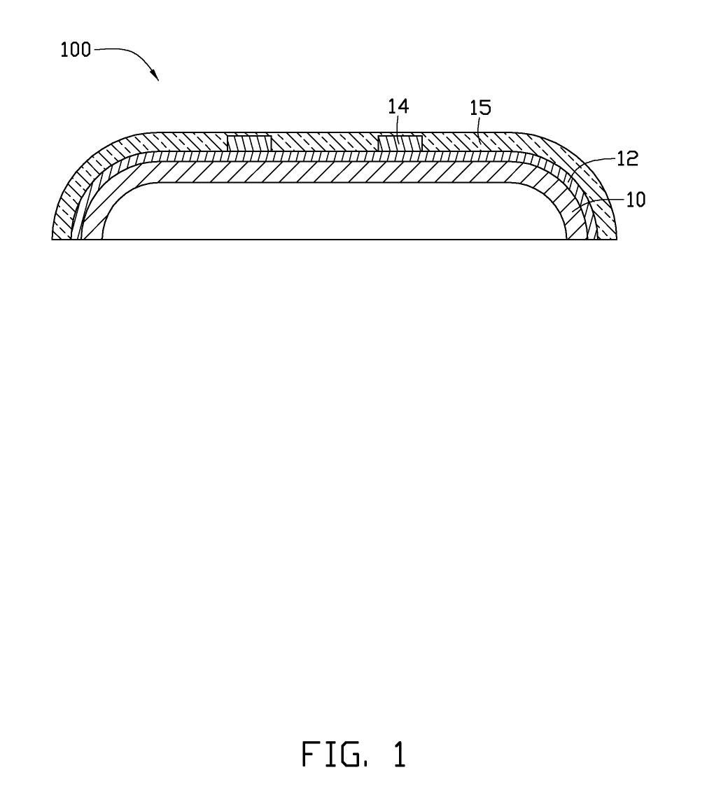

Referring to FIG. 1, an exemplary embodiment of a housing 100 is provide and manufactured by a coating process, such as by vacuum deposition. The housing 100 includes a substrate 10, a color layer 12 deposited on the substrate 10, a pattern layer 14 deposited on the color layer 12 opposite to the substrate 10, and a protection layer 15 deposited on the pattern layer 14 opposite to the color layer 12. The housing 100 may be a housing of an electronic device.

The substrate 10 may be made of metal, glass, ceramic or resin. The color layer 12 is a coating deposited by the vacuum deposition. The color layer 12 has a first color, such as red. The pattern layer 14 may be also a coating deposited by the vacuum deposition, but with a second color different from the first color, such as green. The pattern layer 14 may be a symbol, pattern, or character. The color layer 12 and the pattern layer 14 may both have a metallic sheen. The protection layer 15 is transparent and protects the color layer 12 and the pattern layer 14 from abrasion. When the housing 100 is used in an electronic device with a transmitting/receiving ratio-frequency signal function, the color layer 12 may be a non-conductive vacuum deposition coating.

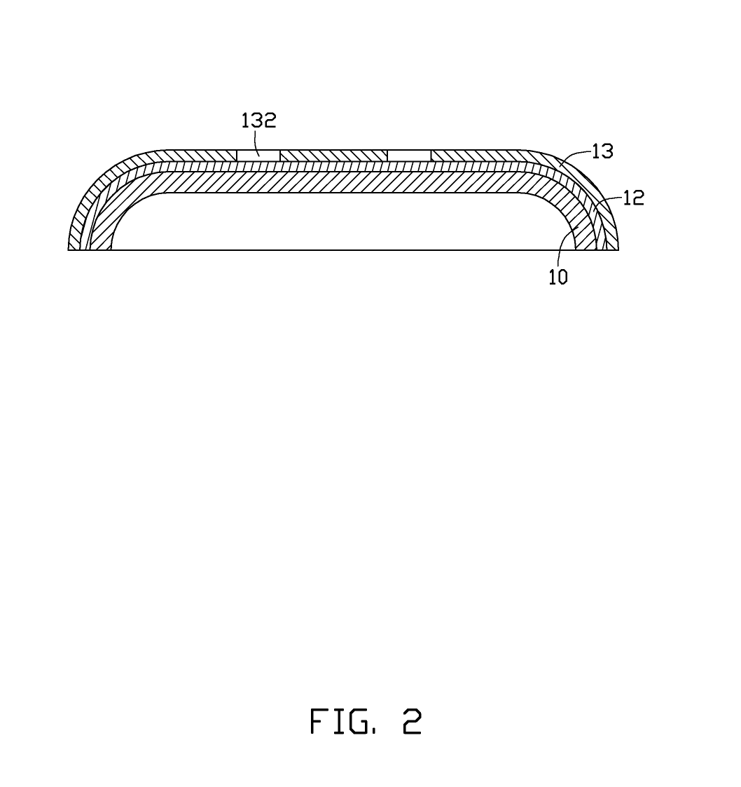

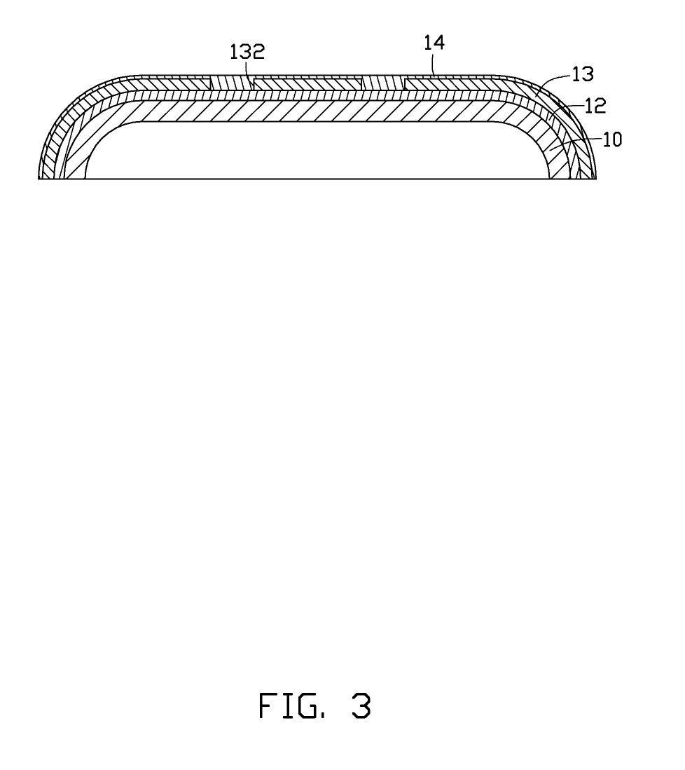

Referring to FIGS. 2 and 3, a method for manufacturing the housing 100 manufactured by vacuum deposition may include at least the following steps.

A substrate 10 is provided. The substrate 10 may be made of metal, glass, resin or ceramic.

The substrate 10 is pretreated. For example, the substrate 10 may be washed with a solution (e.g., alcohol or acetone) in an ultrasonic cleaner to remove grease, dirt, and/or impurities. The substrate 10 is then dried. The substrate 10 may also be cleaned using argon plasma cleaning.

A color layer 12 is deposited on the substrate 10 by vacuum deposition. The color layer 12 has the first color and a metallic sheen. When the housing 100 is used in an electronic device with a transmitting/receiving ratio-frequency signal function, the color layer 12 may be a non-conductive vacuum deposition coating.

Referring to FIG. 2, a glue 13 is provided. The glue defines a plurality of cut-out 132 having the same shape and size as the pattern layer 14. The glue may have high temperature resistance, so the glue cannot be deformed when a pattern layer 14 is deposited on the color layer 12 by the vacuum deposition.

The glue 13 is attached on top of the color layer 12. The color layer 12 is covered by the glue 13 except for portions of the color layer 12 corresponding to the cut-out 132.

Referring to FIG. 3, a pattern layer 14 is deposited on the color layer 12 through the cut-out 132 by vacuum deposition. The pattern layer 14 has a second color different from the first color, such as green. The pattern layer 14 may be a symbol, pattern, or character. The pattern layer 14 has a metallic sheen.

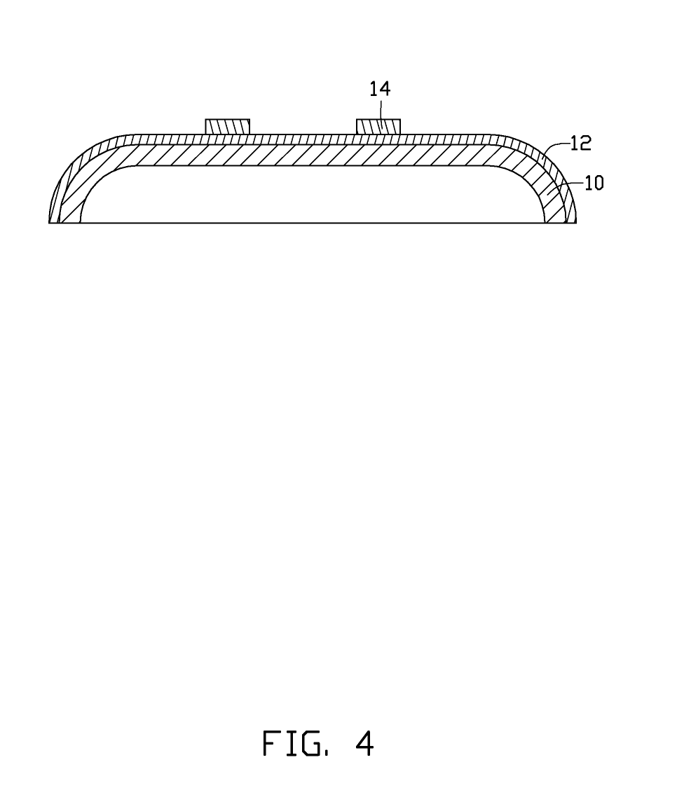

Referring to FIG. 4, the glue 13 is removed from the color layer 12. A protection layer 15 is deposited on the color layer 12 and the pattern layer 14 to protect the color layer 12 and the pattern layer 14. Thus, a housing 100 is yielded.

In above method, after depositing the color layer 12 on the substrate 10, the glue 13 covers on the color layer 12 and the pattern layer 14 is deposited on the color layer 12. After the pattern layer 12 dries, the glue layer 12 is removed. Thus, a housing 100 having a color layer 12 with a first color and a pattern layer 14 with a second color is obtained.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate;
a color layer deposited on the substrate by vacuum deposition, the color layer having a first color; and
a pattern layer deposited on the color layer opposite to the substrate by vacuum deposition, the pattern layer having a second color different from the first color.

2. The housing as claimed in claim 1, further comprising a protection layer deposited on the pattern layer and the color layer.

3. The housing as claimed in claim 1, wherein the substrate is made of metal, glass, ceramic or resin.

4. The housing as claimed in claim 1, wherein the color layer and the pattern layer both have a metallic sheen.

5. The housing as claimed in claim 1, wherein the protection layer is transparent.

6. The housing as claimed in claim 1, wherein the color layer is a non-conductive vacuum deposition coating.

7. A method for manufacturing a housing comprising steps of:
providing a substrate; and
depositing a color layer on the substrate by vacuum deposition, the color layer having a first color;
providing a glue covering on the color layer, the glue defining a cut-out therethrough; and
depositing a pattern layer on the color layer through the cut-out, the pattern layer having a second color different from the first color; and
removing the glue from the color layer.

8. The method of claim 7, wherein the substrate is made of metal, glass, resin or ceramic.

9. The method of claim 7, wherein the color layer has a metallic sheen.

10. The method of claim 7, wherein the color layer is a non-conductive vacuum deposition coating.

11. The method of claim 7, wherein when glue covers on the color layer, a portion of the color layer corresponding to the cut-out is exposed out of the glue, but the reminder of the color layer is covered by the glue; the pattern layer is formed the part of the color layer corresponding to the cut-out.

12. The method of claim 7, wherein the pattern layer is a symbol, pattern, or character.

13. The method of claim 7, wherein the pattern layer has a metallic sheen.
